(19) United States
(12) Patent Application Publication
(10) Pub. No.: US 2025/0351678 A1
(43) Pub. Date: Nov. 13, 2025

(54) DISPLAY PANEL AND DISPLAY DEVICE

(71) Applicant: TIANMA MICROELECTRONICS CO., LTD., Shenzhen City (CN)

(72) Inventors: Huifang Zhou, Shenzhen City (CN); Yanyun Fan, Shenzhen City (CN); Zhongjie Zhang, Shenzhen City (CN)

(73) Assignee: TIANMA MICROELECTRONICS CO., LTD., Shenzhen City (CN)

(21) Appl. No.: 19/275,102

(22) Filed: Jul. 21, 2025

(30) Foreign Application Priority Data
Apr. 28, 2025 (CN) 202510558107.6

(51) Int. Cl. H10K 59/121; G09G 3/3233; H10K 59/131

(52) U.S. Cl. CPC H10K 59/1213; H10K 59/131; G09G 3/3233; G09G 2300/0426; G09G 2300/0842; G09G 2300/0861; G09G 2310/0286; G09G 2380/10

(57) ABSTRACT

A display panel and a display device. The display panel includes a substrate, and a driving layer and a light-emitting device located at a side of the substrate. The driving layer includes inorganic layers. At least one inorganic layer has a hollow. A display region includes a first region and a second region. The first region includes the hollow. The first region includes the light-emitting device. The light-emitting device at least partially overlaps with the hollow along a direction perpendicular to a plane of the substrate. The second region includes the light-emitting device and pixel circuits located in the driving layer. The pixel circuits coupled to the light-emitting device in the first region are located in the second region. The display region includes signal lines, coupled to the pixel circuits, located in the driving layer. At least one signal line penetrates the first and second regions in its extending direction.

### CROSS-REFERENCE TO RELATED APPLICATIONS

The present application claims priority to Chinese patent application No. 202510558107.6, filed on Apr. 28, 2025, which is hereby incorporated by reference in its entirety.

### TECHNICAL FIELD

The present disclosure relates to the field of display technologies, specifically a display panel and a display device.

### BACKGROUND

An organic light-emitting diode (OLED) is a device that generates electroluminescence using a multi-layer organic thin film structure. It is generally easy to manufacture and only requires a low driving voltage, making OLED a common foundation for flat panel displays. Compared to a liquid crystal display, an OLED display screen is thinner and lighter, having high brightness, low power consumption, fast response, high definition, good flexibility, and high luminous efficiency, all of which can meet new demands of consumers on display technologies. The OLED display screen is not only widely used in conventional daily electronic consumer products such as a mobile phone and a tablet, but also in the field of vehicle-mounted displays.

In some special usage scenarios, the display screen may face a risk of impact at high frequency and amplitude, thus making it susceptible to a high risk of fracture. How to improve the impact resistance and ensure the physical integrity of the display screen is an urgent problem to be solved.

### SUMMARY

Embodiments of the present disclosure provide a display panel and a display device to solve a technical problem of improving the impact resistance of the display panel.

In a first aspect, an embodiment of the present disclosure provides a display panel, and the display panel includes a substrate, a driving layer and a light-emitting device. The driving layer and the light-emitting device are located at a side of the substrate, the driving layer includes inorganic layers, and at least one of the inorganic layers has a hollow portion.

The display panel has a display region including a first region and a second region, and the first region has the hollow portion. The first region has the light-emitting device, and the light-emitting device at least partially overlaps with the hollow portion along a direction perpendicular to a plane of the substrate. The second region includes the light-emitting device and a pixel circuit that is located in the driving layer. The pixel circuit that is coupled to the light-emitting device in the first region is located in the second region.

The display region has signal lines located in the driving layer, the signal lines are coupled to the pixel circuits, and at least one of the signal lines penetrates the first region and the second region in an extending direction thereof.

In a second aspect, based on the same inventive concept, an embodiment of the present disclosure further provides a display device, including the display panel according to any embodiment of the present disclosure.

### BRIEF DESCRIPTION OF DRAWINGS

In order to better illustrate the technical solutions in embodiments of the present disclosure or the related art, the drawings used in the description of the embodiments will be briefly illustrated as follows. It should be noted that, the drawings described below are merely some, rather than all of the embodiments of the present disclosure. Based on these drawings, those skilled in the art can obtain other drawings without any creative efforts.

FIG. 1 is a schematic diagram of a display panel according to an embodiment of the present disclosure;

FIG. 2 is an enlarged schematic diagram of a region Q1 shown in FIG. 1;

FIG. 3 is a cross-sectional schematic diagram of a display panel according to an embodiment of the present disclosure;

FIG. 4 is a schematic diagram of a pixel circuit according to an embodiment of the present disclosure;

FIG. 5 is a layout of a pixel circuit according to an embodiment of the present disclosure;

FIG. 6 is another layout of a pixel circuit according to an embodiment of the present disclosure;

FIG. 7 is a cross-sectional schematic diagram of another display panel according to an embodiment of the present disclosure;

FIG. 8 is a top view of a hollow portion pattern according to an embodiment of the present disclosure;

FIG. 9 is a partial schematic diagram of another display panel according to an embodiment of the present disclosure;

FIG. 10 is a schematic diagram of another display panel according to an embodiment of the present disclosure;

FIG. 11 is a partial schematic diagram of another display panel according to an embodiment of the present disclosure;

FIG. 12 is a partial schematic diagram of another display panel according to an embodiment of the present disclosure;

FIG. 13 is a partial schematic diagram of another display panel according to an embodiment of the present disclosure;

FIG. 14 is a schematic diagram of another display panel according to an embodiment of the present disclosure;

FIG. 15 is a schematic diagram of another display panel according to an embodiment of the present disclosure;

FIG. 16 is a schematic diagram of another display panel according to an embodiment of the present disclosure;

FIG. 17 is a schematic diagram of another display panel according to an embodiment of the present disclosure;

FIG. 18 is a partial schematic diagram of another display panel according to an embodiment of the present disclosure;

FIG. 19 is a partial schematic diagram of another display panel according to an embodiment of the present disclosure;

FIG. 20 is a partial schematic diagram of another display panel according to an embodiment of the present disclosure;

FIG. 21 is a partial schematic diagram of another display panel according to an embodiment of the present disclosure; and

FIG. 22 is a schematic diagram of a display device according to an embodiment of the present disclosure.

### DESCRIPTION OF EMBODIMENTS

In order to more clearly illustrate objectives, technical solutions, and advantages of embodiments of the present disclosure, the technical solutions in embodiments of the present disclosure are clearly and completely described in detail with reference to the drawings. It should be noted that the embodiments described are only some rather than all of the embodiments of the present disclosure. Based on the embodiments of the present disclosure, all other embodiments obtained by those ordinary skilled in the art without creative efforts shall fall within a scope of the present disclosure.

Terms used in the embodiments of the present disclosure are only for the purpose of describing specific embodiments and are not intended to limit the present disclosure. Singular forms of “a/an”, “said” and “the” used in the embodiments of the present disclosure and the appended claims are also intended to include plural forms, unless explicitly indicating other meanings.

An embodiment of the present disclosure provides a display panel in which at least one inorganic layer of the display panel is provided with a hollow portion, and at least part of the hollow portion is arranged in a display region. In the display region, a light-emitting device overlaps with the hollow portion at a position of the hollow portion, and the pixel circuits which are initially required to be arranged at the position of the hollow portion are concentrated in an area without the hollow portion of the inorganic layer. According to the present disclosure, without affecting the overall arrangement of light-emitting devices in the display region, the inorganic layer is cut off at a local position using the hollow portion of the inorganic layer, thereby providing a buffer when subjected to stress. When the display panel is impacted, even if a crack appears locally in the inorganic layer, the crack can be arrested when extending to the position of the hollow portion, thereby suppressing the propagation of crack to the entire display region and improving the impact resistance. The present disclosure may illustrate this concept below in specific embodiments.

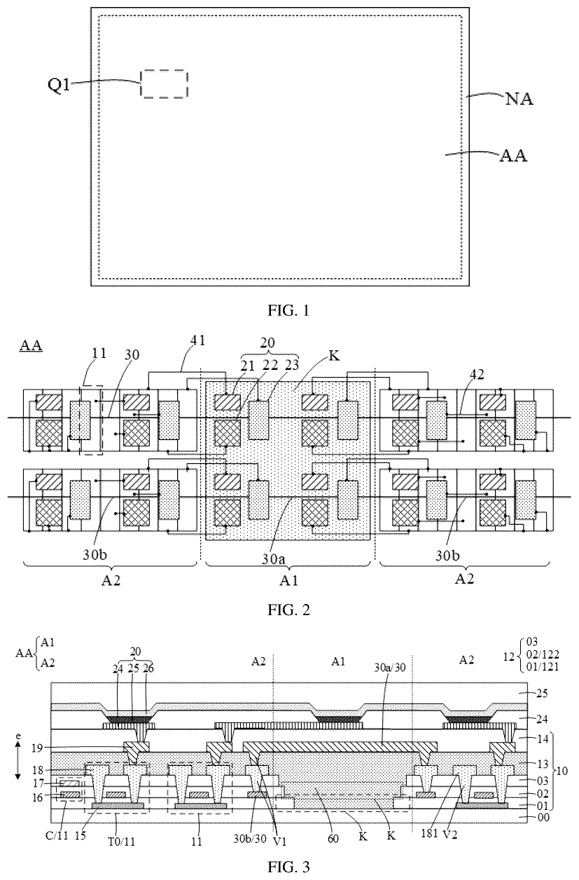

FIG. 1 is a schematic diagram of a display panel according to an embodiment of the present disclosure, and FIG. 2 is an enlarged schematic diagram of a region Q1 shown in FIG. 1. According to the exemplary embodiment shown in FIG. 1, the display panel includes a display region AA and a non-display region NA. FIG. 2 shows a simplified schematic diagram of the region Q1. A light-emitting device 20 and a pixel circuit 11 are provided in the display region AA. The display region AA includes a first region A1 and a second region A2. The first region A1 includes the light-emitting device 20, and the second region A2 includes the light-emitting device 20 and the pixel circuit 11. The pixel circuit 11 coupled to the light-emitting device 20 in the first region A1 may be located in the second region A2. The light-emitting device 20 includes a first light-emitting device 21, a second light-emitting device 22, and a third light-emitting device 23 that have different colors. In an embodiment, the first light-emitting device 21 is a red light-emitting device, the second light-emitting device 22 is a green light-emitting device, and the third light-emitting device 23 is a blue light-emitting device. The arrangement of the light-emitting devices 20 in FIG. 2 is merely illustrative and not intended to limit the present disclosure. FIG. 2 shows the arrangement of the light-emitting devices 20 at a local position of the display region AA. In an embodiment of the present disclosure, the light-emitting devices 20 in the entire display region AA are arranged in a regular array.

It should be understood that FIG. 2 shows that the first region A1 includes 2 rows by 2 columns of pixel units, wherein each pixel unit includes 3 sub-pixels. In an actual product, a plurality of rows and a plurality of columns of pixel units may be provided in the first region A1, and the specific number of arrangements may be adjusted according to actual conditions, which is not specifically limited in the present disclosure.

FIG. 3 is a cross-sectional schematic diagram of a display panel according to an embodiment of the present disclosure. FIG. 3 shows a film layer structure of the display panel. According to the exemplary embodiment shown in FIG. 3, the display panel includes a substrate 00 and a driving layer 10 located at a side of the substrate 00. The pixel circuit 11 is located in the driving layer 10, and the light-emitting device 20 is located at a side of the driving layer 10 away from the substrate 00. In some embodiments, the light-emitting device 20 includes a first electrode 24, a light-emitting layer 25 and a second electrode 26 that are stacked on one another, and the first electrode 24 is located at a side of the second electrode 26 adjacent to the substrate 00. The first electrodes 24 of the light-emitting devices 20 are isolated from each other, and the second electrodes 26 of the light-emitting devices 20 are connected to each other to form a common electrode. In some embodiments, the display panel further includes a pixel definition layer 24 configured to space adjacent light-emitting devices 20. An encapsulation layer 25 is further provided at a side of the light-emitting device 20 away from the substrate 00, and the encapsulation layer 25 is configured to isolate water and oxygen, improving a service life of the light-emitting device 20. In some embodiments, the encapsulation layer 25 includes at least one inorganic encapsulation layer and at least one organic encapsulation layer.

According to the illustrated embodiment, the driving layer 10 includes inorganic layers 12, and at least one inorganic layer 12 has a hollow portion K. The driving layer 10 includes a semiconductor layer and metal layers. The inorganic layers 12 may be used to provide interlayer insolation between the semiconductor layer, as well as the metal layers and between adjacent metal layers. In some embodiments of the present disclosure, the hollow portion K may also be understood as a dug-out region of the inorganic layer 12. In the structure of the pixel circuit 11 of the display panel, some structures may be connected to each other through a via hole penetrating the inorganic layer 12, and the inorganic layer 12 is dug out at the position of the via hole. In distinguishing the hollow K of the present disclosure from the via hole of the inorganic layer 12, it should be understood that the via hole may be filled with metal material, whereas the hollow portion K of the present disclosure is not filled with metal material, but may be filled with organic material. Further, an area of the hollow portion K of the present disclosure is much larger than an area of a single via hole.

In the illustrated embodiment, the first region A1 includes the hollow portion K. In other words, at least part of the hollow portion K is located in the first region A1. As can be seen from FIG. 2 and FIG. 3, along a direction e perpendicular to a plane of the substrate 00, the light-emitting device 20 and the hollow portion K at least partially overlap. In an embodiment, the light-emitting devices 20 are connected in one-to-one correspondence to the pixel circuits 11 in the display region AA. In some embodiments, providing the hollow portion K of the inorganic layer 12 in the display region AA does not reduce the number of the pixel circuits 11. The light-emitting device 20 at least partially overlaps with the hollow portion K, and the hollow portion K of the inorganic layer 12 arranged in the display region AA does not affect the initial arrangement manner of the light-emitting devices 20 in the display region AA.

In the illustrated embodiment, the display region AA includes signal lines 30 located in the driving layer 10. The signal lines 30 are coupled to the pixel circuits 11. In some embodiments, the signal lines 30 are traces for driving the pixel circuits 11 to operate. As can be seen from FIG. 2, at least one signal line 30 penetrates the first region A1 and the second region A2 in the extending direction thereof. According to an embodiment of the present disclosure, one signal line 30 may be manufactured using one metal layer, or one signal line 30 may include line segments located in different metal layers, for example, a trace portion of the signal lines 30 located in the first region A1 and a trace portion of the signal lines 30 located in the second region A2 are located in different layers.

According to some embodiments of the present disclosure, at least one inorganic layer 12 in the display panel has the hollow portion K. The first region A1 of the display region AA includes the hollow portion K. The light-emitting device 20 overlaps with the hollow portion K in the first region A1, and the pixel circuits 11 driving the light-emitting device 20 in the first region A1 are arranged in the second region A2 of the display region AA. That is, the hollow portion K of the inorganic layer 12 may be formed at the position where the pixel circuit 11 is initially arranged in the first region A1, and the pixel circuits 11 initially required to be arranged in the first region A1 may be moved to the second region A2. The first region A1 may be used for arranging the hollow portion K in the display region AA, and the second region A2 may be used for concentrating the pixel circuits 11. According to an embodiment of the present disclosure, the pixel circuits 11 are locally concentrated in the second region A2, reserving a position for manufacturing the hollow portion K of the inorganic layer 12 in the first region A1, and the hollow portion K of the inorganic layer 12 is used to truncate the inorganic layer 12 at a local position, thereby providing a buffer when subjected to stress and reducing the risk of fracture of the inorganic layer 12. Further, when the display panel is impacted, even if a crack appears locally in the inorganic layer 12, the crack may be arrested when extending to the position of the hollow portion K, suppressing the propagation of crack to the entire display region AA, thereby improving the impact resistance. Further, in an embodiment where the light-emitting device 20 is located at a side of the driving layer 10 away from the substrate 00, the hollow portion K of the inorganic layer 12 does not affect the manufacturing of the light-emitting device 20 in the display region AA, and it is possible to maintain the positions and the number of the light-emitting devices 20 in the display region AA in the embodiments of the present disclosure. Further, the pixel circuits 11 may be locally concentrated using a layout space under an original PPI (Pixels Per Inch, pixel density), to ensure that the light-emitting devices 20 in the first region A1 can be normally driven.

The embodiments of the present disclosure may be applied to some medium-sized display panels, such as a vehicle-mounted display. An exemplary embodiment of a vehicle-mounted display device is special, facing a large frequency and amplitude of impact, and prone to high screen fracture risk. By adopting the display panel according to the embodiments of the present disclosure, the impact resistance of vehicle-mounted display may be improved, such that the display panel can still normally display when a vehicle suffers a large impact, ensuring that the driver can obtain the vehicle status information.

In an embodiment of the present disclosure, the signal line 30 includes metal. That is, a trace portion of the signal line 30 in the first region A1 and a trace portion of the signal line 30 in the second region A2 are both metal wires. The signal lines 30 may be arranged in the display region AA and may be traces for driving the pixel circuits 11 to operate. In an embodiment of the present disclosure, the problem of the transmittance of the display region AA is not considered, so materials of the signal lines 30 in the first region A1 and the second region A2 do not need to be specially designed.

As shown in the exemplary embodiment illustrated in FIG. 3, the hollow portion K is filled with an organic structure 60. Because the first region A1 includes the hollow portion K, and the first region A1 is a display region, filling the hollow portion K with the organic structure 60 is beneficial to ensuring a uniform flat surface for the entire display region. As such, the light-emitting devices 20 in the first region A1 and the light-emitting devices 20 in the second region A2 may be manufactured on a base surface at the same height, which is beneficial to the light-emitting uniformity of the display panel. The organic structure 60 may further function to buffer stress at the position of the hollow portion K, so as to improve the impact resistance of the display panel.

In the exemplary embodiment illustrated in FIG. 2, the signal line 30 penetrating the first region A1 and the second region A2 includes a first line segment 30a and a second line segment 30b. At least part of the first line segment 30a may be located in the first region A1, and the second line segment 30b may be located in the second region A2. The first line segment 30a and the second line segment 30b may be connected to each other. Referring to FIG. 3, the first line segment 30a may be located at a side of the organic structure 60 away from the substrate 00. The first line segment 30a may be manufactured after the process of filling the hollow portion K with the organic structure 60, so as to avoid the risk that the first line segment 30a is directly manufactured in the hollow portion K and is disconnected at a climbing position in the hollow portion K.

In some embodiments, the first line segment 30a and the second line segment 30b of at least one signal line 30 are located in different layers. In the exemplary embodiment illustrated in FIG. 3, a connection via hole V1 of the first line segment 30a and the second line segment 30b is located in the second region A2. The first line segment 30a and the second line segment 30b located in different layers may be connected to each other through the via hole V1 to ensure the reliable performance of the electrical connection between the first line segment 30a and the second line segment 30b. The via hole V1 may be formed in the second region A2, such that the connection via hole V1 between the first line segment 30a and the second line segment 30b may have a moderate depth in a direction e perpendicular to the substrate 00, thereby avoiding the increment of the processing difficulty of drilling holes in the organic structure 60 with a thicker thickness in the first region A1.

In some embodiments, some of the signal lines 30 includes a first line segment 30a and a second line segment 30b that are located in different layers, that is, the signal lines 30 adopts a line-changing design when passing through the first region A1 from the second region A2. Some of the signal lines 30 may be made of one metal layer, that is, these signal lines 30 do not change lines when passing through the first region A1 from the second region A2.

In the exemplary embodiment shown in FIG. 3, the driving layer 10 includes a first transistor TO and a capacitor C. The driving layer 10 includes a semiconductor layer 15, a first metal layer 16, a second metal layer 17, and a first source-drain electrode layer 18. The first metal layer 16 may be located at a side of the semiconductor layer 15 away from the substrate 00, the second metal layer 17 may be located at a side of the first metal layer 16 away from the substrate 00, and the first source-drain electrode layer 18 may be located at a side of the second metal layer 17 away from the substrate 00. In some embodiments, the semiconductor layer 15 includes an active layer of the first transistor TO, the first metal layer 16 includes a gate of the first transistor TO and a first electrode plate of the capacitor C, the second metal layer 17 includes a second electrode plate of the capacitor C, the first source-drain electrode layer 18 includes connection structures 181, and at least some of the connection structures 181 are electrically connected to the active layer of the first transistor TO through a via hole V2, respectively. Some of the connection structures 181 are marked in FIG. 3, and the connection structures 181 are further illustrated in the following embodiments of designing the layout of the pixel circuit 11. The first transistor TO (as shown in FIG. 3) may be one transistor in the pixel circuit 11, and the capacitor C may be, for example, a storage capacitor in the pixel circuit 11.

In an embodiment of the present disclosure, the semiconductor layer 15 includes silicon, the first metal layer 16 and the second metal layer 17 include molybdenum, the first source-drain electrode layer 18 includes titanium and aluminum, and the first source-drain electrode layer 18 is a three-layer structure of titanium/aluminum/titanium.

As shown in FIG. 3, inorganic layers 12a may be provided at a side of the first source-drain electrode layer 18 adjacent to the substrate 00. For example, an inorganic layer 01 may be provided between the semiconductor layer 15 and the first metal layer 16, an inorganic layer 02 is provided between the first metal layer 16 and the second metal layer 17, and an inorganic layer 03 may be provided between the second metal layer 17 and the first source-drain electrode layer 18. A first organic layer 13 may be provided at a side of the first source-drain electrode layer 18 away from the substrate 00, and the hollow portion K may be filled with the first organic layer 13. That is, the first organic layer 13 may be reused as the organic structure 60. In some embodiments, the film layer of the first source-drain electrode layer 18 has a relatively large thickness in the direction e perpendicular to the substrate 00. The first organic layer 13 manufactured after the process of the first source-drain electrode layer 18 may provide good coverage of the pattern structure of the first source-drain electrode layer 18 and avoid exposure of metal. Meanwhile, the first organic layer 13 may also operate in planarization on the first source-drain electrode layer 18, such that the structure manufactured after the process of the first source-drain electrode layer 18 may be formed on a relatively flat substrate. As such, the thickness of the first organic layer 13 may be relatively thick. In some embodiments of the present disclosure, the first organic layer 13 is used to fill the hollow portion K, which may further operate to buffer stress at the position of the hollow portion K, thereby improving the impact resistance of the display panel without adding new fabrication process.

In some embodiments, such as the illustrative embodiment shown in FIG. 3, the driving layer 10 further includes a second source-drain electrode layer 19 located at a side of the first organic layer 13 away from the substrate 00, and a second organic layer 14 located at a side of the second source-drain electrode layer 19 away from the substrate 00. In the first region A1, the second source-drain electrode layer 19 includes at least one signal line 30. In other words, at least one signal line 30 in the first region A1 may be located in the second source-drain electrode layer 19. As shown in FIG. 3, the first line segment 30a of the signal line 30 may be located in the second source-drain electrode layer 19. The second source-drain electrode layer 19 may be an original metal layer in the display panel. Alternatively, the second source-drain electrode layer 19 may be an additional metal layer added to meet wiring requirements of the signal line 30 in the first region A1. The second source-drain electrode layer 19 may be made of the same material as the first source-drain electrode layer 18. In some embodiments, the second organic layer 14 manufactured on the second source-drain electrode layer 19 serves as a planarization layer, which may provide good coverage on the pattern structure in the second source-drain electrode layer 19, while providing a flat substrate for the light-emitting device 20 manufactured on the driving layer 10, thereby ensuring the brightness uniformity in the display region.

Further, in an embodiment of the present disclosure, the pixel circuits 11 for driving the light-emitting device 20 in the first region A1 are arranged in the second region A2, such that no wiring and related structures in the pixel circuits 11 are provided in the semiconductor layer 15, the first metal layer 16, the second metal layer 17 and the first source-drain electrode layer 18 in the first region A1.

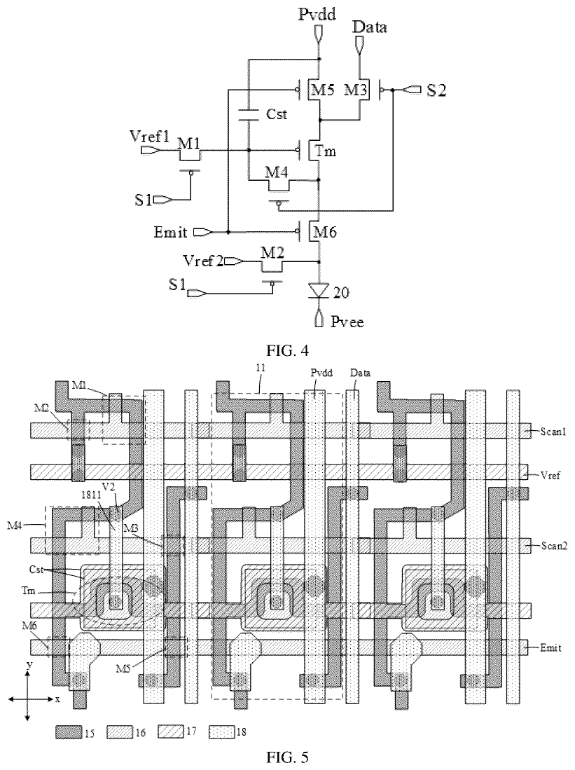

FIG. 4 is a schematic diagram of a pixel circuit according to an embodiment of the present disclosure. In the illustrated embodiment, the pixel circuit includes a driving transistor Tm, a gate reset transistor M1, an electrode reset transistor M2, a data writing transistor M3, a threshold compensation transistor M4, a first light-emitting control transistor M5, a second light-emitting control transistor M6, and a storage capacitor Cst. The driving transistor Tm may be connected in series between the first light-emitting control transistor M5 and the second light-emitting control transistor M6, in some embodiments, a control terminal of the gate reset transistor M1 and a control terminal of the electrode reset transistor M2 receive a scanning signal S1. A first electrode of the gate reset transistor M1 receives a reset signal Vref1, and a second electrode of the gate reset transistor M1 may be connected to a control terminal of the driving transistor Tm. In some embodiments, a first electrode of the electrode reset transistor M2 receives a reset signal Vref2, and a second electrode of the electrode reset transistor M2 is connected to a first electrode of the light-emitting device 20. A control terminal of the data writing transistor M3 and a control terminal of the threshold compensation transistor M4 may receive a scanning signal S2. A first electrode of the data writing transistor M3 may receive a data signal Data, a second electrode of the data writing transistor M3 may be connected to a first electrode of the driving transistor Tm. The threshold compensation transistor M4 may be connected between the control terminal and a second electrode of the driving transistor Tm. In some embodiments, a control terminal of the first light-emitting control transistor M5 and a control terminal of the second light-emitting control transistor M6 receive a light-emitting control signal Emit, a first electrode of the first light-emitting control transistor M5 receives a first power supply voltage Pvdd, and a second electrode of the light-emitting device 20 receives a second power supply voltage Pvee. In an embodiment, the first power supply voltage Pvdd is a positive power supply voltage, and the second power supply voltage Pvee is a negative power supply voltage.

FIG. 4 illustrates that the control terminal of the electrode reset transistor M2 and the control terminal of the gate reset transistor M1 may receive the same signal. In some other embodiments, the control terminal of the electrode reset transistor M2 may also receive the same signal as the control terminal of the data writing transistor M3.

FIG. 4 illustrates that the first electrode of the electrode reset transistor M2 and the first electrode of the gate reset transistor M1 may receive different reset signals, and a voltage value of the reset signal Vref1 and a voltage value of the reset signal Vref2 may be different. In an embodiment, the voltage value of the reset signal Vref2 is less than the voltage value of the reset signal Vref1. A lower reset voltage may be provided to an electrode of the light-emitting device 20, so that unintended illumination of the light-emitting device 20 may be reduced, thereby improving low gray level display performance. Meanwhile, providing a higher reset voltage to the gate of the driving transistor Tm may make the threshold capture of the gate of the driving transistor Tm faster. When applied to high-frequency display or low-brightness (or gray level) display, the threshold capture time of the gate of the driving transistor Tm may be shorter. The faster the threshold capture of the gate of the driving transistor Tm is, the more accurate the threshold capture may be, thereby reducing display non-uniformity and improving the display effect.

In some other embodiments, the first electrode of the electrode reset transistor M2 and the first electrode of the gate reset transistor M1 receive the same reset voltage. The first electrode of the electrode reset transistor M2 and the first electrode of the gate reset transistor M1 may also be electrically connected to the same reset signal line.

In some embodiments, the gate reset transistor M1 and the threshold compensation transistor M4 are dual-gate transistors.

FIG. 4 only illustrates that the pixel circuit includes seven transistors and one capacitor as an example; however, the embodiments of the present disclosure are also applicable to other pixel circuit structures.

FIG. 5 is a layout of a pixel circuit according to an embodiment of the present disclosure. The connection relationship of each transistor in the pixel circuit 11 should be understood in combination with FIG. 4. FIG. 5 depicts three pixel circuits 11 arranged in a first direction x. According to an embodiment of the present disclosure, the first electrode of the electrode reset transistor M2 and the first electrode of the gate reset transistor M1 receive the same reset signal, which is provided by a reset signal line Vref. The display panel may be provided with a first scanning line Scan1, a second scanning line Scan2, a reset signal line Vref, a light-emitting control line Emit, a data line Data, and a first power supply signal line Pvdd. In some embodiments, the first scanning line Scan1, the second scanning line Scan2, the reset signal line Vref, and the light-emitting control line Emit extend along a first direction x, and the data line Data and the first power supply signal line Pvdd extend along a second direction y. The first direction x may intersect with the second direction y. In some embodiments, the first scanning line Scan1 provides a scanning signal to the control terminal of the electrode reset transistor M2 and the control terminal of the gate reset transistor M1. In some embodiments, the second scanning line Scan2 provides a scanning signal to the control terminal of the data writing transistor M3 and the control terminal of the threshold compensation transistor M4. In some embodiments, the light-emitting control line Emit provides a light-emitting control signal Emit, the data line Data provides a data signal Data, and the first power supply signal line Pvdd provides a first power supply voltage Pvdd. The first scanning line Scan1, the second scanning line Scan2 and the light-emitting control line Emit may be located in the first metal layer 16, the reset signal line Vref may be located in the second metal layer 17, and the data line Data and the first power supply signal line Pvdd may be located in the first source-drain electrode layer 18.

FIG. 5 shows a first connection structure 1811 connected to the control terminal of the threshold compensation transistor M4 and the control terminal of the driving transistor Tm. The first connection structure 1811 may be located in the first source-drain electrode layer 18, and the first connection structure 1811 may be electrically connected to the active layer of the threshold compensation transistor M4 located in the semiconductor layer 15 through the via hole V2.

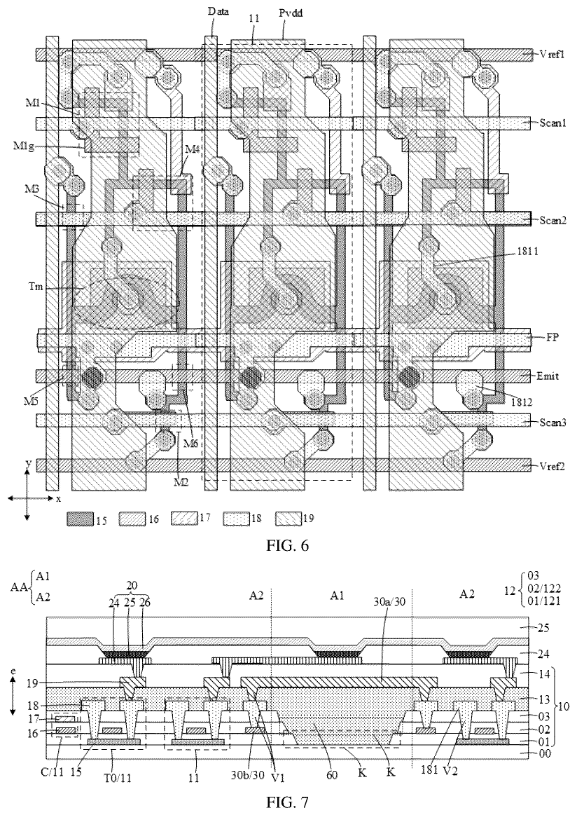

FIG. 6 is another layout of a pixel circuit according to an embodiment of the present disclosure. The connection relationship of each transistor in the pixel circuit 11 should be understood in combination with FIG. 4. FIG. 6 depicts three pixel circuits 11 arranged in a first direction x. According to an embodiment of the present disclosure, the first electrode of the electrode reset transistor M2 and the first electrode of the gate reset transistor M1 receive different reset signals. The display panel may be provided with a first scanning line Scan1, a second scanning line Scan2, a third scanning line Scan3, a first reset signal line Vref1, a second reset signal line Vref2, a light-emitting control line Emit, and a data line Data and a first power supply signal line Pvdd. In some embodiments, the first scanning line Scan1, the second scanning line Scan2, the third scanning line Scan3, the first reset signal line Vref1, the second reset signal line Vref2, and the light-emitting control line Emit extend along a first direction x. Conversely, the data line Data and the first power supply signal line Pvdd extend along a second direction y. In some embodiments, the first scanning line Scan1 provides a scanning signal to the control terminal of the gate reset transistor M1, the second scanning line Scan2 provides a scanning signal to the control terminal of the data writing transistor M3 and the control terminal of the threshold compensation transistor M4, and the third scanning line Scan3 provides a scanning signal to the control terminal of the electrode reset transistor M1. In some embodiments, he light-emitting control line Emit provides a light-emitting control signal Emit, the data line Data provides a data signal Data, and the first power supply signal line Pvdd provides a first power supply voltage Pvdd. In some embodiments, the first reset signal line Vref1 provides a reset signal Vref1, and the second reset signal line Vref2 provides a reset signal Vref2. FIG. 6 illustrates that the display panel may be further provided with a power supply auxiliary line FP that intersects with and may be electrically connected to the first power supply signal line Pvdd.

In an embodiment of FIG. 6, the first scanning line Scan1, the second scanning line Scan2 and the third scanning line Scan3 are located in the first source-drain electrode layer 18, and the gates of transistors connected to these scanning lines are located in the first metal layer 16. Taking the gate reset transistor M1 as an example, FIG. 6 shows that a gate M1g (i.e., the control terminal) of the gate reset transistor M1 may be located in the first metal layer 16, and the gate M1g may be electrically connected to the first scanning line Scan1 through a via hole. A sheet resistance of the first source-drain electrode layer 18 may be smaller than a sheet resistance of the first metal layer 16. Manufacturing the scanning line on the first source-drain electrode layer 18 may reduce the voltage drop on the scanning line and thus improve the display uniformity.

In an embodiment of FIG. 6, the first reset signal line Vref1, the second reset signal line Vref2 and the light-emitting control line Emit are located in the first metal layer 16, the power supply auxiliary line FP is located in the first source-drain electrode layer 18, and the data line Data and the first power supply signal line Pvdd are located in the second source-drain electrode layer 19.

FIG. 6 shows a first connection structure 1811 and a second connection structure 1812 located in the first source-drain electrode layer 18. The first connection structure 1811 may be connected to the control terminal of the threshold compensation transistor M4 and the control terminal of the driving transistor Tm, and the second connection structure 1812 may be connected to a signal output terminal of the pixel circuit 11 and the first electrode of the light-emitting device 20.

In some embodiments, a length of the display region AA of the display panel in the first direction x is relatively large. In some embodiments, the number of pixel circuits 11 connected to one scanning line in the medium-sized display panel is relatively large. By adopting the design of the embodiments of FIG. 6, three scanning lines may be provided for one pixel circuit row, and the gate reset transistor M1, the data writing transistor M3 and the electrode reset transistor M2 in the pixel circuit 11 may be driven by the three scanning lines, respectively, ensuring the driving capability of the scanning lines, reducing the voltage drop on the scanning lines, and improving the display uniformity.

It should be understood that, referring to FIG. 5 and FIG. 6, the first reset signal line Vref1 and the second reset signal line Vref2 may be arranged parallel to the extending direction of the data line Data, and may be located in the same film layer as the data line Data.

In some embodiments, as shown in FIG. 3, the inorganic layer 12 includes a first inorganic layer 121 and a second inorganic layer 122, and the first inorganic layer 121 and the second inorganic layer 122 include the hollow portion K, respectively. In a part of the display region AA, the first inorganic layer 121 and the second inorganic layer 122 may be in contact with each other. The first inorganic layer 121 and the second inorganic layer 122 may be adjacent inorganic layers, meaning that the hollow portion K of the first inorganic layer 121 overlaps with the hollow portion K of the second inorganic layer 122 to form a hollow portion with a greater depth along the direction e. According to the exemplary embodiment shown in FIG. 3, the inorganic layer 01 between the semiconductor layer 15 and the first metal layer 16 is the first inorganic layer 121, and the inorganic layer 02 between the first metal layer 16 and the second metal layer 17 is the second inorganic layer 122. As such, an edge of the hollow portion K of the first inorganic layer 121 and an edge of the hollow portion K of the second inorganic layer 122 form a step. FIG. 3 shows that an inner wall of the hollow portion K may be perpendicular to a plane of the substrate 00. When the hollow portion K is filled with the organic structure 60, the design of the step may increase the contact area between the organic structure 60 and the inorganic layer, thereby enhancing the bonding strength between the organic structure 60 and the inorganic layer, and improving the mechanical stability of the display panel.

FIG. 7 is a cross-sectional schematic diagram of another display panel according to an embodiment of the present disclosure. As shown in FIG. 7, the first inorganic layer 121 and the second inorganic layer 122 may each include the hollow portion K. The first inorganic layer 121 and the second inorganic layer 122 may be in contact with each other in a part of the display region AA, and an edge of the first inorganic layer 121 and an edge of the second inorganic layer 122 adjacent to the hollow portion K may both include an inclined surface. That is, the inner wall of the hollow portion K may be an inclined surface relative to the substrate 00. Such configuration may increase the contact area between the organic structure 60 and the inorganic layer, thereby enhancing the bonding strength between the organic structure 60 and the inorganic layer and improving the mechanical stability of the display panel.

In some embodiments, as shown in the top view of FIG. 2, the shape of the hollow portion K is a rectangle. It should be understood that in the exemplary embodiment depicted in FIG. 2, an edge of an orthographic projection of the hollow portion K on the plane of the substrate 00 is a straight line. In other embodiments, an edge of the orthographic projection of the hollow portion K on the plane of the substrate 00 is a curve.

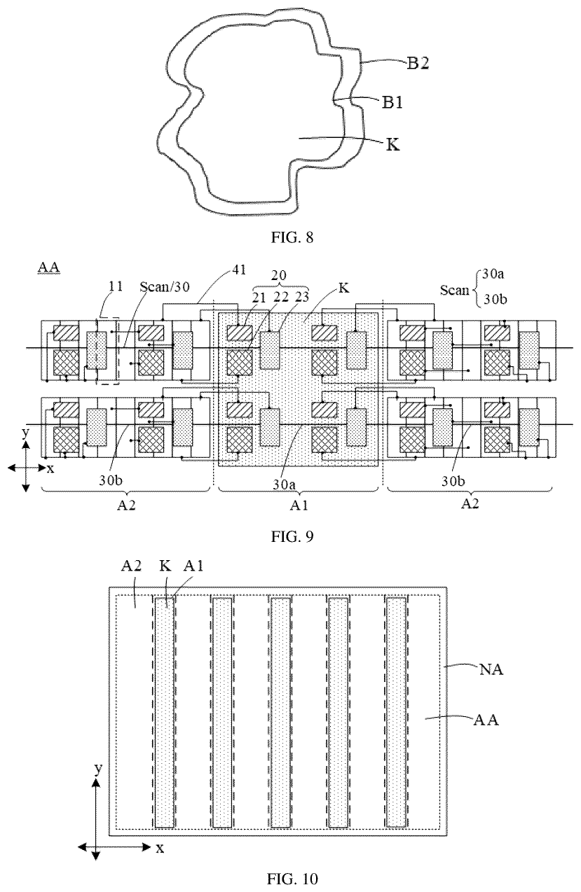

FIG. 8 is a top view of a hollow pattern according to an embodiment of the present disclosure According to the exemplary embodiment illustrated in FIG. 8, which shows the top view of one hollow portion K in the inorganic layer 12, an edge B1 is a hollow edge formed on a surface of the inorganic layer 12 at a side adjacent to the substrate 00, and an edge B2 is a hollow edge formed on a surface of the inorganic layer 12 at a side away from the substrate 00. It should be understood that in the embodiments of FIG. 8, an inner wall of the hollow portion K may be an inclined surface relative to the substrate 00. In an exemplary embodiment such as the one illustrated in FIG. 8, the edge of an orthographic projection of the hollow portion K on the plane of the substrate 00 is a curve. Such a configuration may further improve the impact resistance of the display panel.

In some embodiments, the edge of the orthographic projection of the hollow portion K on the plane of the substrate 00 is a wavy line.

In some embodiments, as shown in FIG. 2, the display panel includes a first connection line 41. One end of the first connection line 41 may be coupled to the light-emitting device 20 located in the first region A1, and the other end of the first connection line 41 may be coupled to the pixel circuit 11 located in the second region A2. With reference to a film layer structure of the display panel shown in FIG. 3, the driving layer 10 may include a first organic layer 13, and the light-emitting device 20 may be located at a side of the first organic layer 13 away from the substrate 00. In some embodiments, he light-emitting device 20 includes a first electrode 24, a light-emitting layer 25 and a second electrode 26 that are stacked on one another, and the first electrode 24 is located at a side of the second electrode 26 adjacent to the substrate 00. The first connection line 41 may be located at a side of the first organic layer 13 away from the substrate 00. The first connection line 41 may be introduced from the first region A1 to the second region A2. In combination with the solution of filling the first organic layer 13 in the hollow portion K, the first connection line 41 may be arranged at a side of the first organic layer 13 away from the substrate 00, such that the first connection line 41 may be manufactured on a relatively flat substrate. The first connection line 41 may be prevented from disconnection caused by climbing at the edge of the hollow portion K when routing within the hollow portion K, while reducing the distance between the first connection line 41 and the light-emitting device 20 in the direction e perpendicular to the substrate 00, thereby reducing the connection difficulty between the first connection line 41 and the light-emitting device 20.

In some embodiments, at least part of at least one first connection line 41 is in the same layer as the first electrode 24. The first connection line 41 may extend from the first region A1 to the second region A2 to connect the corresponding pixel circuit 11. The first connection line 41 and the first electrode 24 may be arranged in the same layer, such that the first connection line 41 and the first electrode 24 may be manufactured in the same process and electrically connected to each other. In the first region A1, the first connection line 41 and the first electrode 24 may be connected to each other without drilling holes, resulting in a simple process.

In some embodiments, at least part of the first connection line 41 located in the first region A1 is in the same layer as the first electrode 24.

In other embodiments, at least part of at least one first connection line 41 is located in the first source-drain electrode layer 18. In other embodiments, at least part of at least one first connection line 41 is located in the second source-drain electrode layer 19. In application, the film layer of the first connection line 41 may be designed according to the wiring position of the first connection line 41. For example, when two first connection lines 41 cross each other in the wiring, in order to avoid short circuit, one of the two first connection lines 41 may be performed with a line-changing design. For example, the first connection line 41 with the line-changing design includes a line segment located in the same layer as the first electrode 24, and a line segment located in the first source-drain electrode layer 18 (or the second source-drain electrode layer 19).

As shown in FIG. 2, the display panel may include a second connection line 42 located in the second region A2. In the second region A2, at least one light-emitting device 20 does not overlap with the pixel circuit 11 coupled thereto in a direction perpendicular to the plane of the substrate 00. The light-emitting device 20 may be electrically connected to the pixel circuit 11 through the second connection line 42. In an embodiment of the present disclosure, the pixel circuits 11 for driving the light-emitting devices 20 in the first region A1 are arranged in the second region A2, and the pixel circuits 11 for driving the light-emitting devices 20 in the second region A2 are also arranged in the second region A2, such that the pixel circuits 11 in the second region A2 are arranged relatively closely, and some of the light-emitting devices 20 do not overlap with the pixel circuit 11 connected thereto. At this time, the light-emitting device 20 and the pixel circuit 11 connected thereto may be electrically connected through the second connection line 42. In an embodiment, at least one second connection line 42 may be arranged in the same layer as the first connection line 41. The second connection line 42, the first connection line 41 and the first electrode 24 may be arranged in the same layer. In the second region A2, the wiring space of the film layer of the first electrode 24 may be sufficient. The second connection line 42 may be arranged in the same layer as the first electrode 24, such that the second connection line 42 may be electrically connected to the light-emitting device 20 without affecting the wiring of the pixel circuit 11.

In some embodiments, at least part of at least one second connection line 42 is located in the first source-drain electrode layer 18. In other embodiments, at least part of at least one second connection line 42 is located in the second source-drain electrode layer 19.

In some embodiments, referring to FIG. 5 and FIG. 6, the display region AA includes scanning lines extending along the first direction x. FIG. 5 shows that the scanning lines may include a first scanning line Scan1 and a second scanning line Scan2, while FIG. 6 shows that the scanning lines may include a first scanning line Scan1, a second scanning line Scan2 and a third scanning line Scan3. The first region A1 and the second region A2 arranged in the display panel may be adjacent in the first direction x.

FIG. 9 is a partial schematic diagram of another display panel according to an embodiment of the present disclosure, illustrating a partial position of the display region AA. As shown in FIG. 9, the first region A1 and the second region A2 may be adjacent to each other in the first direction x. In the second region A2, the pixel circuits 11 may be arranged along the first direction x. The scanning line Scan extending in the first direction x penetrates the first region A1 and the second region A2, and one scanning line Scan may be electrically connected to the pixel circuits 11 arranged in the first direction x. That is, the signal line 30 includes a scanning line Scan including a first line segment 30a and a second line segment 30b. In combination with the layouts shown in FIG. 5 and FIG. 6, the layout of the pixel circuit 11 may be generally elongated, and its length in the first direction x may be less than its length in the second direction y. In order to ensure the driving capability of the driving transistor Tm, there may be requirements for a channel width-to-length ratio of the driving transistor Tm, such that the occupied area of the driving transistor Tm is larger. In order to cooperate with the connection of the driving transistor Tm, when arranging and designing the pixel circuit 11, its length in the first direction x is relatively easier to be compressed. In an embodiment of the present disclosure, the first region A1 and the second region A2 may be arranged adjacent to each other in the first direction x, the pixel circuit 11 for driving the light-emitting device 20 in the first region A1 may be arranged in the second region A2, and the pixel circuit 11 may be arranged closely in the second region A2 more easily.

FIG. 10 is a schematic diagram of another display panel according to an embodiment of the present disclosure. As shown in FIG. 10, in the display region AA, the first region A1 and the second region A2 may be alternately arranged in the first direction x. In some embodiments, the inorganic layer has a hollow portion K in the first region A1. In an embodiment, strip-shaped inorganic layer dug-out regions are formed in the display region AA, and the stress borne by the inorganic layer is buffered using the hollow portion K when the display panel is subjected to impact, thereby reducing the risk of fracture of the inorganic layer. In some embodiments, when a crack occurs in the inorganic layer in the second region A2 due to impact, the crack is arrested at the position of the hollow portion K in the first region A1 when propagating along the first direction x, suppressing the propagation of crack to the adjacent second region A2, thereby further improving the overall impact resistance of the display panel.

In some embodiments, as shown in FIG. 9, the display panel includes a first connection line 41. One end of the first connection line 41 may be coupled to the light-emitting device 20 located in the first region A1, and the other end of the first connection line 41 may be coupled to the pixel circuit 11 located in the second region A2. The first region A1 may be located between two second regions A2 adjacent to each other in the first direction x. Among the first connection lines 41 connected to the light-emitting devices 20 in the first region A1, some of the first connection lines 41 extend to the second region A2 located at one side of the first region A1, and some of the first connection lines 41 extend to the second region A2 located at the other side of the first region A1. That is, the light-emitting devices 20 in the first region A1 draw wires to the left and right directions to connect to the pixel circuits 11 in the two second regions A2 on both sides, respectively. When a length of the first region A1 in the first direction x or a width of the hollow portion K in the first direction x is determined, the design of some embodiments of the present disclosure may be equivalent to that the pixel circuits 11 connected to the light-emitting devices 20 in the first region A1 are dispersedly arranged in the two second regions A2. On the one hand, it may reduce a misalignment distance in the first direction x between the light-emitting device 20 and the pixel circuit 11 connected thereto in the first region A1, thereby reducing the wiring length of the first connection line 41 and reducing the voltage drop. On the other hand, the number of the first connection lines 41 introduced from the first region A1 to one second region A2 may be reduced, which may reduce the wiring space for arranging the first connection lines 41 on the single side of the first region A1 in the first direction x and reduce the wiring difficulty of the first connection lines 41.

In some embodiments, as shown in FIG. 9, among the first connection lines 41 connected to the light-emitting devices 20 in the first region A1, the number of the first connection lines 41 extending to the second regions A2 located at the first side of the first region A1 is equal to the number of the first connection lines 41 extending to the second regions A2 located at the second side of the first region A1. As shown in FIG. 9, in one circuit row where the pixel circuit 11 are arranged along the first direction x, three first connection lines 41 in the first region A1 may be connected to the second region A2 on the left side, and three first connection lines 41 are connected to the second region A2 on the right side. Such a configuration may reduce a length difference of the first connection line 41 drawing wires to both sides of the first region A1, such that a voltage drop difference on the first connection lines 41 is small, which may improve the display uniformity.

FIG. 11 is a partial schematic diagram of another display panel according to an embodiment of the present disclosure. As shown in FIG. 11, the display panel may include a first connection line 41. One end of the first connection line 41 may be coupled to the light-emitting device 20 located in the first region A1, and the other end of the first connection line 41 may be coupled to the pixel circuit 11 located in the second region A2. In some embodiments, the first connection lines 41 connected to the light-emitting devices 20 in the first region A1 extend to the second region A2 located at the same side as the first region A1. According to the illustrated embodiment, the wiring in the display region AA can be more regular. FIG. 11 shows two first regions A1 and two second regions A2. Adjacent first region A1 and second region A2 form a group, and the wiring manner of the first connection lines 41 and the arrangement manner of the pixel circuits 11 in the two groups are the same, improving the etching uniformity during the manufacturing of the display panel, thereby improving the display uniformity.

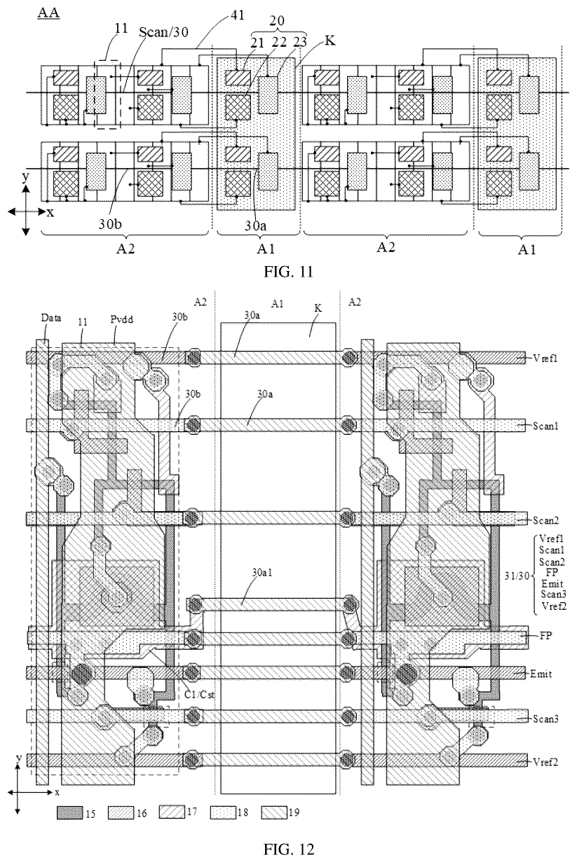

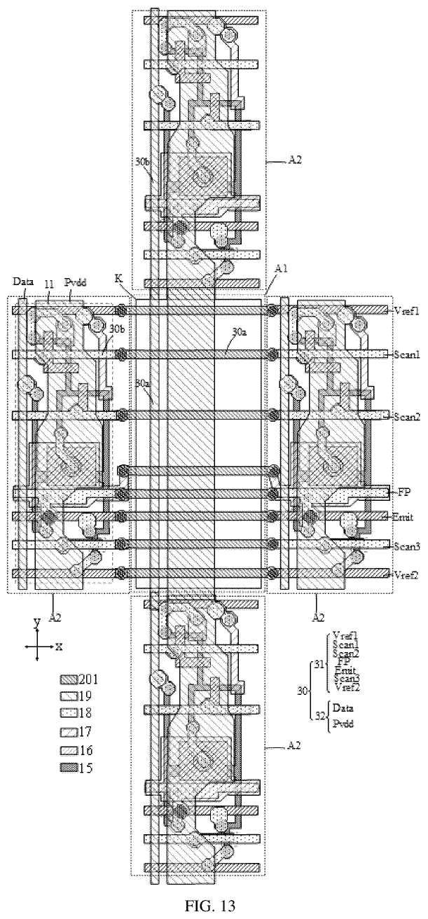

FIG. 12 is a partial schematic diagram of another display panel according to an embodiment of the present disclosure. It should be understood that the exemplary pixel circuit 11 in FIG. 12 is illustrated with the layout of the pixel circuit shown in FIG. 6. As shown in FIG. 12, the signal lines 30 penetrate the first region A1 and the second region A2 in an extending direction thereof. The signal line 30 may include a first line segment 30a and a second line segment 30b electrically connected to each other. At least part of the first line segment 30a may be located in the first region A1, and the second line segment 30b may be located in the second region A2. The signal lines 30 include first signal lines 31 extending along the first direction x. The first line segment 30a and the second line segment 30b of the first signal line 31 may be located in different layers. In some embodiments, the first signal lines 31 include a first scanning line Scan1, a second scanning line Scan2, a third scanning line Scan3, a first reset signal line Vref1, a second reset signal line Vref2, and a light-emitting control line Emit. Taking the first reset signal line Vref1 as an example, it can be seen from FIG. 12 that a first line segment 30a of the first reset signal line Vref1 may be located in the second source-drain electrode layer 19, and a second line segment 30b of the first reset signal line Vref1 may be located in the first metal layer 16. The first segment 30a and the second segment 30b of the first reset signal line Vref1 may be located in different layers.

In combination with the film layer structure of the display panel shown in FIG. 3, the first metal layer 16, the second metal layer 17 and the first source-drain electrode layer 18 may all be located at a side of the first organic layer 13 adjacent to the substrate 00. That is, the first organic layer 13 may be manufactured after the process of the first source-drain electrode layer 18. In an embodiment of the present disclosure, in order to avoid the risk of the disconnection of the signal line when climbing, caused by manufacturing the signal line inside the hollow portion K of the inorganic layer 12, the signal line 30 in the first region A1 may be arranged at a side of the first organic layer 13 away from the substrate 00. Therefore, the first line segment 30a of the signal line 30 located in the first region A1 may be manufactured after the process of the first organic layer 13, such that the first signal line 31 extending along the first direction x adopts a line-changing design to ensure that the first signal line 31 penetrates the first region A1 and the second region A2 in the extending direction thereof.

FIG. 12 illustrates that the first line segment 30a of the first signal line 31 may be located in the second source-drain electrode layer 19. In other embodiments, an additional metal layer may also be added to manufacture the first line segment 30a of the first signal line 31.

In other embodiments, the first line segments 30a of the first signal lines 31 are arranged in two metal layers to avoid that the connection via holes are between the first line segments 30a and the second line segments 30b too concentrated due to the manufacturing in the same layer.

FIG. 12 shows that a second electrode plate C2 of the storage capacitor Cst located in the second metal layer 17 may be electrically connected through a line segment 30al spanning the first region A1, and the line segment 30al and the first line segment 30a may be located in the same layer. In this way, the second electrode plates C2 in two adjacent second regions A2 in the first direction x are electrically connected to each other, which may further reduce the voltage drop of the transmitted power supply signal and improve the in-plane uniformity.

In other embodiments, the display panel is provided with a power supply auxiliary line FP extending along the first direction x and a first power supply voltage Pvdd extending along the second direction y. The power supply auxiliary line FP may be connected to the first power supply voltage Pvdd through a via hole, and the power supply auxiliary line FP may be electrically connected to the second electrode plate C2 of the storage capacitor Cst located in the second metal layer 17 through the via hole. The power supply auxiliary line FP intersects with and may be electrically connected to the first power supply signal line Pvdd vertically and horizontally, which may reduce the voltage drop of the transmitted power supply signal.

FIG. 13 is a partial schematic diagram of another display panel according to an embodiment of the present disclosure. As shown in FIG. 13, at least one first region A1 may be located between two second regions A2 adjacent in the first direction x, and the first region A1 may be located between two second regions A2 adjacent in the second direction y. The second direction y may intersect with the first direction x. According to the embodiment, the second region A2 may be arranged around the first region A1, and the hollow portion K of the inorganic layer in the first region A1 may be used to buffer the stress withstood in the surrounding directions. Further, the hollow portion K in the first region A1 may also block the cracks of the inorganic layers extending from the second region A2 to the first region A1 along the first direction x, and may also block the cracks of the inorganic layers extending from the second region A2 to the first region A1 along the second direction y, which may block cracks extending in multiple directions, thereby improving the impact resistance of the display panel.

According to the exemplary embodiment shown in FIG. 13, the signal lines 30 includes first signal lines 31 extending along the first direction x and second signal lines 32 extending along the second direction y. In the first region A1, the first signal lines 31 and the second signal lines 32 may intersect with each other in an insulated manner. The first signal lines 31 in the first region A1 electrically connect the lines on both sides of the first direction x in the first region A1, and the second signal lines 32 in the first region A1 electrically connect the lines on both sides of the second direction y in the first region A1. For example, the first signal line 31 includes a first scanning line Scan1, a second scanning line Scan2, a third scanning line Scan3, a first reset signal line Vref1, a second reset signal line Vref2, and a light-emitting control line Emit, and the second signal line 32 includes a data line Data and a first power supply signal line Pvdd.

In some embodiments, as shown in FIG. 13, the signal line 30 includes a first line segment 30a and a second line segment 30b that are electrically connected to each other. At least part of the first line segment 30a may be located in the first region A1, and the second line segment 30b may be located in the second region A2. The first line segment 30a and the second line segment 30b of the first signal line 31 may be located in different layers. The first line segment 30a and the second line segment 30b of the second signal line 32 may be located in the same layer. In combination with the film layer structure shown in FIG. 3, the second line segment 30b of the first signal line 31 located in the second region A2 may be manufactured in the manufacturing process of the first transistor TO and the capacitor C in the driving layer 10. The first line segment 30a and the second line segment 30b of the first signal line 31 may be arranged in different layers, so that the first line segment 30a of the first signal line 31 may be manufactured at a side of the first organic layer 13 away from the substrate 00, avoiding the disconnection of the first signal line 31 when climbing within the hollow portion K. Further, for the second signal line 32, the data line Data and the first power supply signal line Pvdd in the second signal lines 32 may be arranged in the second source-drain electrode layer 19, and the second source-drain electrode layer 19 may be located at a side of the first organic layer 13 away from the substrate 00. Since there is no transistor structure of the pixel circuit in the first region A, the line-changing design may not be necessary when the second signal line 32 extends from the second region A2 to the first region A1 along the second direction y, that is, the first line segment 30a and the second line segment 30b of the second signal line 32 may be arranged in the same layer, which may reduce the number of holes in the insulating layer in the second region A2 and save the wiring space occupied in the second region A2.

In some embodiments, the first line segment 30a of the first signal line 31 is located in a third metal layer 201, and the first line segment 30a of the second signal line 32 is located in the second source-drain electrode layer 19. The third metal layer 201 may be an additional metal layer in the display panel located either at a side of the second source-drain electrode layer 19 adjacent to the substrate 00, or a side of the second source-drain electrode layer 19 away from the substrate 00.

In other embodiments, in the first region A1, the first signal line 31 and the second signal line 32 cross each other in an insulated manner. The first line segment 30a and the second line segment 30b of the first signal line 31 may be located in different layers, and the first line segment 30a and the second line segment 30b of the second signal line 32 may be located in different layers, which will not be further illustrated herein.

FIG. 14 is a schematic diagram of another display panel according to an embodiment of the present disclosure. As shown in FIG. 14, in the display region AA, the first regions A1 and the second regions A2 may be alternately arranged in the first direction x, and the first regions A1 and the second regions A2 may be alternately arranged in the second direction y. In the display region AA, the first region A1 and the second region A2 may be arranged in a staggered manner to form an arrangement manner similar to a checkerboard format. According to an embodiment, the hollow portions K in the first region A1 are uniformly arranged in an array in the display region AA, the second region A2 is surrounded by the first region A1, and the stress withstood by the inorganic layer in the second region A2 can be dispersed in four directions, thereby reducing the risk of fracture of the inorganic layer. Further, the hollow portions K in the four first regions A1 in the four directions may cooperate to block the cracks of the inorganic layers extending from the second region A2 to the first region A1 along the first direction x, and may also block the cracks of the inorganic layers extending from the second region A2 to the first region A1 along the second direction y, which may block cracks extending in multiple directions, and thus improve the impact resistance of the display panel.

The above embodiments describe the solution that the first region A1 in the display region AA includes the hollow portion K of the inorganic layer 12. In some embodiments of the present disclosure, the hollow portion K of the inorganic layer 12 is further provided in the non-display region NA.

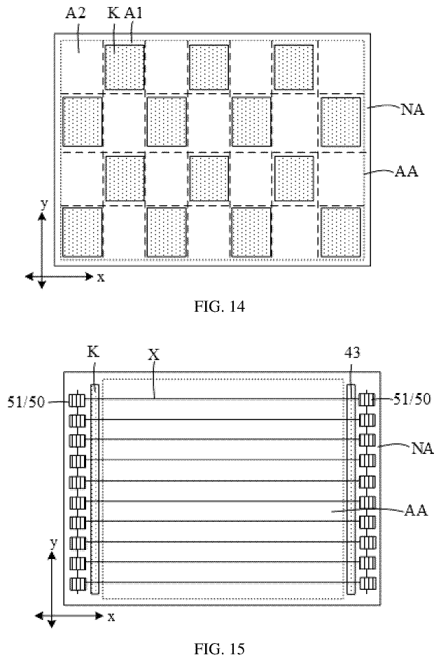

FIG. 15 is a schematic diagram of another display panel according to an embodiment of the present disclosure. As shown in FIG. 15, the display panel may further include a shift register unit 50 located in the non-display region NA. In some embodiments, the shift register unit 50 includes a first shift register unit 51, and a plurality of first shift register units 51 are cascaded. A hollow portion K may be provided at a side of the first shift register unit 51 adjacent to the display region AA. The shift register unit 50 may be any circuit structure in the related art that can implement a signal shift function, and the shift register unit 50 may be only a simplified illustration in an embodiment of FIG. 15.

FIG. 15 shows that first shift register units 51 may be provided both sides of the display region AA in the first direction x, respectively, and the first shift register units 51 may be arranged along the second direction y in the non-display region NA on one side of the display region AA. Gate lines X extending along the first direction x may be provided in the display region AA, the gate line X may be electrically connected to an output terminal of the first shift register unit 51, and the gate lines X may be connected to pixel circuits arranged in the first direction x. The gate line X may be any one of the first scanning line Scan1, the second scanning line Scan2, the third scanning line Scan3, and the light-emitting control line Emit shown in the embodiments of FIG. 6. The first region A1 and the second region A2 in an embodiment of FIG. 15 may be designed as shown in FIG. 10 or FIG. 14.

In an embodiment of the present disclosure, at least one inorganic layer 12 has a hollow portion K in a region between the first shift register unit 51 and the display region AA, and the hollow portion K disconnects the inorganic layer at the position of the first shift register unit 51 from the inorganic layer in the display region AA. In some embodiments, the hollow portion K arranged in the non-display region NA provides stress buffering when the display panel is subjected to stress. Further, cracks only appears locally in the inorganic layer, and do not extend from the position of the first shift register unit 51 to the display region AA, nor do they extend from the display region AA to the position of the first shift register unit 51, thereby further improving the impact resistance of the display panel.

Further, as shown in FIG. 15, a third connection line 43 located in the non-display region NA may be connected to the output terminal of the first shift register unit 51 and the gate line X located in the display region AA. As can be seen from the top view of FIG. 15, the third connection line 43 overlaps with the hollow portion K along a direction perpendicular to the plane of the substrate 00. In an embodiment, the hollow portion K is filled with the first organic layer 13 as shown in FIG. 3, and the third connection line 43 is located at a side of the first organic layer 13 away from the substrate 00. FIG. 15 illustrates that an elongated hollow portion K may be provided in the non-display region NA, and the hollow portion K may be adjacent to the cascaded first shift register units 51.

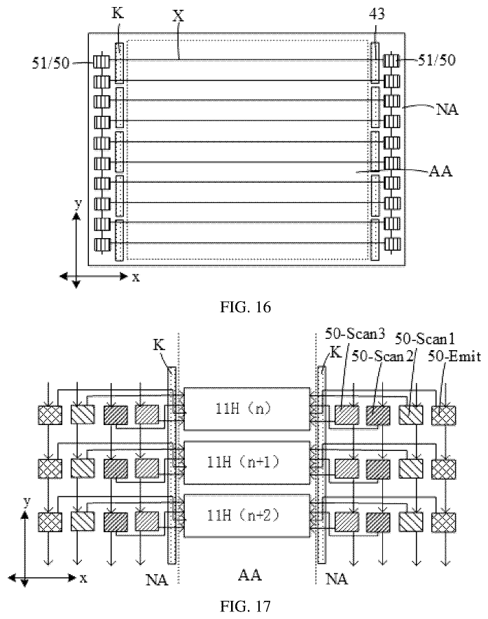

FIG. 16 is a schematic diagram of another display panel according to an embodiment of the present disclosure. As shown in FIG. 16, in the non-display region NA on the side of the first direction x in the display region AA, hollow portions K arranged along the first direction x may be provided between the cascaded first shift register units 51 and the display region AA.

FIG. 17 is a schematic diagram of another display panel according to an embodiment of the present disclosure. FIG. 17 illustrates an arrangement manner of shift register units 50 in the non-display region NA of the display panel. As shown in FIG. 17, the shift register unit 50 may include a first scanning shift register unit 50-Scan1, a second scanning shift register unit 50-Scan2, a third scanning shift register unit 50-Scan3, and a light-emitting shift register unit 50-Emit. In combination with FIG. 6, an output terminal of the first scanning shift register unit 50-Scan1 may be connected to the first scanning line Scan1, an output terminal of the second scanning shift register unit 50-Scan2 may be connected to the second scanning line Scan2, an output terminal of the third scanning shift register unit 50-Scan3 may be connected to the third scanning line Scan3, and an output terminal of the light-emitting shift register unit 50-Emit may be connected to the light-emitting control line Emit. In the non-display region NA at a side of the display region AA, the third scanning shift register unit 50-Scan3, the second scanning shift register unit 50-Scan2, the first scanning shift register unit 50-Scan1, and the light-emitting shift register unit 50-Emit may be sequentially arranged away from the display region AA.

FIG. 17 illustrates a number n pixel circuit row 11H (n), a number (n+1) pixel circuit row 11H (n+1), and a number (n+2) pixel circuit row 11H (n+2) in the display region AA, where n is a positive integer. The pixel circuits 11 may be arranged in one pixel circuit row 11H in the first direction x. A group of the second scanning shift register units 50-Scan2, the first scanning shift register units 50-Scan1, the third scanning shift register units 50-Scan3, and the light-emitting shift register units 50-Emit drives one pixel circuit row.

As shown in FIG. 17, a hollow portion K may be provided between the third scanning shift register unit 50-Scan3 and the display region AA. The third scanning shift register unit 50-Scan3 may be equivalent to the first shift register unit 51 in the embodiments of FIG. 15. In other words, the first shift register unit 51 may include the third scanning shift register unit 50-Scan3.

In an embodiment of the present disclosure, the first shift register unit 51 includes any one of the second scanning shift register unit 50-Scan2, the first scanning shift register unit 50-Scan1, the third scanning shift register unit 50-Scan3, and the light-emitting shift register unit 50-Emit.

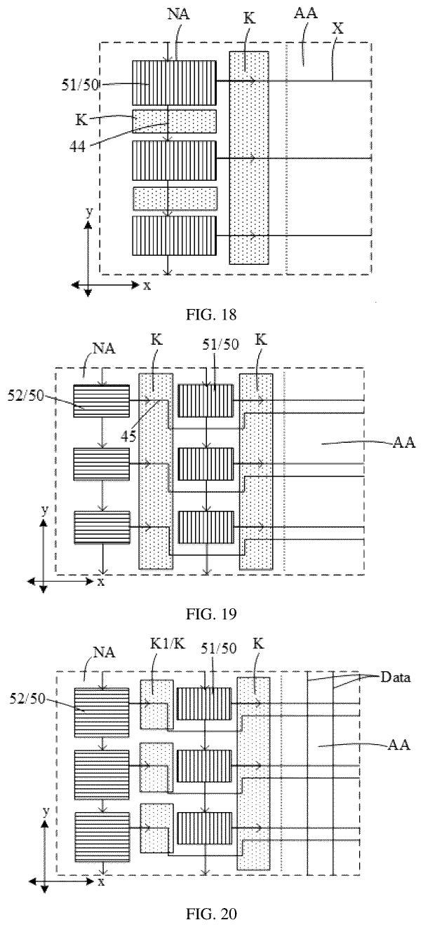

FIG. 18 is a partial schematic diagram of another display panel according to an embodiment of the present disclosure. As shown in FIG. 18, the first shift register units 51 may be arranged and cascaded in the second direction y. In an arrangement direction of the first shift register units 51, a hollow portion K may be provided between two adjacent first shift register units 51. In an embodiment of the present disclosure, the hollow portion K may be provided at a side of the first shift register unit 51 adjacent to the display region AA, and the hollow portion K may be provided between two adjacent first shift register units 51. That is, a stress buffer structure may be provided at a position adjacent to the first shift register unit 51 in the first direction x and a position adjacent to the first shift register unit 51 in the second direction y, so as to better disperse the stress around the first shift register unit 51, and better protect the first shift register unit 51 when the display panel is subjected to impact, thereby enhancing the impact resistance of the display panel.

FIG. 18 illustrates that the hollow portion K arranged on a side of the first shift register unit 51 adjacent to the display region AA may not be connected to the hollow portion K arranged between two adjacent first shift register units 51. In other embodiments, the hollow portion K arranged on a side of the first shift register unit 51 adjacent to the display region AA may be connected to the hollow portion K arranged between two adjacent first shift register units 51, which is not illustrated herein.

As shown in FIG. 18, a cascade signal line 44 may be connected to and between two adjacent stages of first shift register units 51. It can be seen from the top view that the cascade signal line 44 overlaps with the hollow portion K. In an embodiment, the hollow portion K may be filled with the first organic layer 13 as shown in FIG. 3, and the cascade signal line 44 may be located at a side of the first organic layer 13 away from the substrate 00. Such configuration m prevent the disconnection of the cascade signal line 44 when climbing within the hollow portion K, ensuring the transmission of the cascade signal.

FIG. 19 is a partial schematic diagram of another display panel according to an embodiment of the present disclosure. As shown in FIG. 19, the shift register unit 50 may include a second shift register unit 52 located at a side of the first shift register unit 51 away from the display region AA. A hollow portion K may be provided between the first shift register unit 51 and the second shift register unit 52. In an embodiment, the hollow portion K may buffer stress between the first shift register unit 51 and the second shift register unit 52, and the crack generated in the inorganic layer may be arrested after being impacted from propagating between the first shift register unit 51 and the second shift register unit 52, thereby ensuring that the first shift register unit 51 and the second shift register unit 52 are electrically stable, and further improving the impact resistance of the display panel.

As can be seen from FIG. 19, at least part of a lead 45 connected to an output terminal of the second shift register unit 52 may overlap with the hollow portion K. In an embodiment, the first organic layer 13 may be filled with the hollow portion K, and at least part of the lead 45 is arranged at a side of the first organic layer 13 away from the substrate 00, so as to further improve the impact resistance, and avoid the disconnection of the lead 45 due to climbing within the hollow portion K.

In combination with FIG. 17, for example, the first shift register unit 51 may be the third scanning shift register unit 50-Scan3, and the second shift register unit 52 may be the second scanning shift register unit 50-Scan2. Alternatively, the first shift register unit 51 is the first scanning shift register unit 50-Scan1, and the second shift register unit 52 is the light-emitting shift register unit 50-Emit.

In some embodiments, the first shift register unit 51 and the second shift register unit 52 have the same circuit structure.

In other embodiments, the first shift register unit 51 and the second shift register unit 52 have different circuit structures. For example, the first shift register unit 51 may include any one of the first scanning shift register unit 50-Scan1, the second scanning shift register unit 50-Scan2, and the third scanning shift register unit 50-Scan3, and the second shift register unit 52 includes the light-emitting shift register unit 50-Emit. The first shift register unit 51 and the second shift register unit 52 may both have a signal shift function, but the numbers of transistors and/or the numbers of capacitors included therein are different from each other.

In some embodiments, FIG. 20 is a partial schematic diagram of another display panel according to an embodiment of the present disclosure. As shown in FIG. 20, the shift register unit 50 may include a first shift register unit 51 and a second shift register unit 52. For example, a length of the second shift register unit 52 in the second direction y may be greater than a length of the first shift register unit 51 in the second direction y. In some embodiments, the display region AA includes a data line Data located in the driving layer 10, and the data line Data extends along the second direction y. In some embodiments, the hollow portion K includes a first hollow portion K1 located between the first shift register unit 51 and the second shift register unit 52. As can be seen from FIG. 20, along the second direction y in which the data line Data extends, a length of the first hollow portion K1 may be greater than the length of the first shift register unit 51. Such arrangement may use the first hollow portion K1 to buffer the stress within a length range of the first shift register unit 51 in the second direction y, and may block the cracks of the inorganic layer on one side of the first shift register unit 51, preventing the cracks of the inorganic layer from extending from a direction of the first shift register unit 51 to a direction of the second shift register unit 52, thereby improving the impact resistance of the display panel.

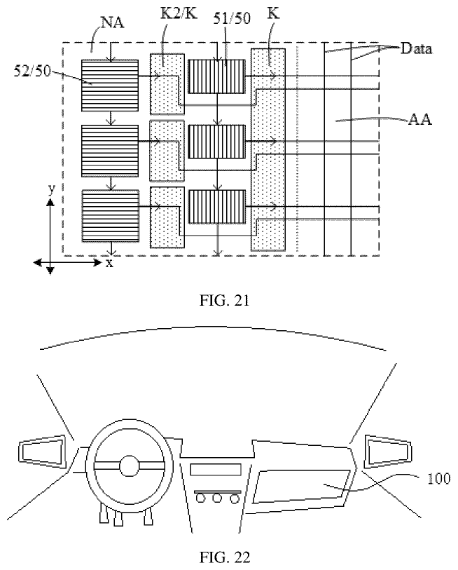

FIG. 21 is a partial schematic diagram of another display panel according to an embodiment of the present disclosure. As shown in FIG. 21, the shift register unit 50 may include a first shift register unit 51 and a second shift register unit 52. For example, a length of the second shift register unit 52 in the second direction y may be greater than a length of the first shift register unit 51 in the second direction y. In some embodiments, the hollow portion K includes a second hollow portion K2 located between the first shift register unit 51 and the second shift register unit 52. As can be seen from FIG. 21, along the second direction y in which the data line Data extends, a length of the second hollow portion K2 may be greater than the length of the second shift register unit 52. Such an arrangement may use the second hollow portion K2 to buffer the stress within a length range of the second shift register unit 52 in the second direction y, and may block the cracks of the inorganic layer on one side of the second shift register unit 52, which in turn may prevent the cracks of the inorganic layer from extending from a direction of the second shift register unit 52 to a direction of the first shift register unit 51. This may also prevent the cracks of the inorganic layer from extending from the direction of the first shift register unit 51 to the direction of the second shift register unit 52, thereby effectively improving the impact resistance of the display panel.

In some embodiments, hollow portions K may be provided between the cascaded first shift register units 51 and the cascaded second shift register units 52. As shown in FIG. 21, in an arrangement direction of the cascaded shift register units 50, one hollow portion K may be provided between each adjacent first shift register unit 51 and second shift register unit 52.

In some other embodiments, hollow portions K may be provided between the cascaded first shift register units 51 and the cascaded second shift register units 52. As shown in FIG. 19, a length of the hollow portion K in the second direction y may be greater than a total length of two or three second shift register units 52 in the second direction y.

Based on the same inventive concept, an embodiment of the present disclosure further provides a display device. FIG. 22 is a schematic diagram of a display device according to an embodiment of the present disclosure. As shown in FIG. 22, the display device may include the display panel 100 according to any embodiment of the present disclosure. The structure of the display panel has been described in the above embodiments, which will not be repeated herein. The display device according to the embodiments of the present disclosure may also be a vehicle-mounted display device. The display device according to the embodiments of the present disclosure may be, for example, an electronic device having a display function, such as a tablet, a mobile phone, a computer, or a television.

The above description merely illustrates some preferred embodiments of the present disclosure, but is not intended to limit the present disclosure, and any modification, equivalent substitution, improvement and the like made within the spirit and the principle of the present disclosure shall fall with the scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate;
a driving layer; and
a light-emitting device,
wherein the driving layer and the light-emitting device are provided at a side of the substrate, the driving layer comprises a plurality of inorganic layers, and at least one of the plurality of inorganic layers has a hollow portion;
wherein the display panel has a display region comprising a first region and a second region, and the first region comprises the hollow portion;
wherein the first region comprises the light-emitting device, the light-emitting device at least partially overlaps with the hollow portion along a direction perpendicular to a plane of the substrate, the second region comprises the light-emitting device and pixel circuits located in the driving layer, and the pixel circuits coupled to the light-emitting device in the first region are located in the second region; and
wherein the display region comprises signal lines located in the driving layer, the signal lines are coupled to pixel circuits, and at least one of the signal lines penetrates the first region and the second region in an extending direction thereof.

2. The display panel according to claim 1,
wherein the signal lines are made of materials comprising metal; or
wherein an edge of an orthographic projection of the hollow portion on the plane of the substrate is a straight line or a curve.

3. The display panel according to claim 1, wherein
the plurality of inorganic layers comprise a first inorganic layer and a second inorganic layer, and the first inorganic layer and the second inorganic layer respectively comprise the hollow portion, and
the first inorganic layer is in contact with the second inorganic layer in a part of the display region, and an edge of the hollow portion of the first inorganic layer and an edge of the hollow portion of the second inorganic layer form a step; or an edge of the first inorganic layer and an edge of the second inorganic layer that are adjacent to the hollow portion each comprise an inclined surface; or wherein
at least one of the signal lines comprises a first line segment and a second line segment that are electrically connected to each other, at least part of the first line segment is located in the first region, and the second line segment is located in the second region, and
the first line segment and the second line segment of the at least one of the signal lines are located in different layers, and a connection via hole of the first line segment and the second line segment are located in the second region.

4. The display panel according to claim 1, wherein
an organic structure is filled in the hollow portion.

5. The display panel according to claim 4, wherein
at least one of the signal lines comprises a first line segment, and at least part of the first line segment is located in the first region; and
the first line segment is located at a side of the organic structure away from the substrate.

6. The display panel according to claim 1, further comprising:
a first connection line, wherein a first end of the first connection line is coupled to the light-emitting device in the first region, and a second end of the first connection line is coupled to at least one of the pixel circuits in the second region;
wherein the driving layer comprises a first organic layer, and the light-emitting device is located at a side of the first organic layer away from the substrate;
wherein the light-emitting device comprises a first electrode, a light-emitting layer and a second electrode that are stacked on one another, and the first electrode is located at a side of the second electrode adjacent to the substrate; and
wherein the first connection line is located at a side of the first organic layer away from the substrate.

7. The display panel according to claim 6, wherein
at least part of at least one first connection line are in a same layer as the first electrode; or
wherein
the display panel further comprises second connection lines located in the second region, in the second region, at least one light-emitting device does not overlap with the pixel circuits coupled thereto in the direction perpendicular to the plane of the substrate, and the at least one light-emitting device is electrically connected to at least one of the pixel circuits through at least one of the second connection lines, and
at least one of the second connection lines and the first connection line are in a same layer.

8. The display panel according to claim 1,
wherein the driving layer has a first transistor and a capacitor; wherein the driving layer comprises a semiconductor layer, a first metal layer, a second metal layer and a first source-drain electrode layer, the first metal layer is located at a side of the semiconductor layer away from the substrate, the second metal layer is located at a side of the first metal layer away from the substrate, and the first source-drain electrode layer is located at a side of the second metal layer away from the substrate;
wherein the semiconductor layer comprises an active layer of the first transistor, the first metal layer comprises a gate of the first transistor and a first electrode plate of the capacitor, the second metal layer comprises a second electrode plate of the capacitor, the first source-drain electrode layer comprises connection structures, and at least part of the connection structures are electrically connected to the active layer of the first transistor through a via hole; and
wherein the plurality of inorganic layers are provided at a side of the first source-drain electrode layer adjacent to the substrate, a first organic layer is provided at a side of the first source-drain electrode layer away from the substrate, and the first organic layer is filled in the hollow portion.

9. The display panel according to claim 8, wherein
the driving layer further comprises a second source-drain electrode layer located at a side of the first organic layer away from the substrate, and a second organic layer located at a side of the second source-drain electrode layer away from the substrate; and
in the first region, the second source-drain electrode layer comprises at least one of the signal lines.

10. The display panel according to claim 1, wherein
the display region comprises scanning lines extending along a first direction; and
in the second region, the pixel circuits are arranged along the first direction; and the first region and the second region are adjacent to each other in the first direction.

11. The display panel according to claim 1, wherein
first regions and second regions are alternately arranged in the first direction; or
wherein the display panel further comprises first connection lines,
a first end of at least one of the first connection lines is coupled to the light-emitting device in the first region, and a second end of the at least one of the first connection lines is coupled to at least one of the pixel circuits in the second region, and
the first connection lines connected to light-emitting devices in the first region extend to the second region located at a same side as the first region.

12. The display panel according to claim 10, wherein
the display panel further comprises first connection lines,
a first end of at least one of the first connection lines is coupled to the light-emitting device in the first region, and a second end of the at least one of the first connection line is coupled to at least one of the pixel circuits in the second region,
the first region is located between two adjacent second regions, and
in the first connection lines connected to light-emitting devices in the first region, a part of the first connection lines extend to the second region located at a first side of the first region, and a part of the first connection lines extend to the second region located at a second side of the first region; or
wherein
at least one of the signal lines comprises a first line segment and a second line segment that are electrically connected to each other, at least part of the first line segment is located in the first region, and the second line segment is located in the second region;
the signal lines comprise a first signal line extending in the first direction; and
a first line segment and a second line segment of the first signal lines are in different layers.

13. The display panel according to claim 12, wherein
among the first connection lines connected to the light-emitting devices in the first region, a line number of the first connection lines extending to the second region on the first side of the first region equals to a line number of the first connection lines extending to the second region on the second side of the first region.

14. The display panel according to claim 10, wherein
at least one first region is located between two adjacent second regions in the first direction, the at least one first region is located between two adjacent second regions in a second direction, and the second direction intersects with the first direction.

15. The display panel according to claim 14, wherein
in the display region, first regions and second regions are alternately arranged in the first direction, and the first regions and the second regions are alternately arranged in the second direction.

16. The display panel according to claim 14, wherein
the signal lines comprise a first signal line extending in the first direction and a second signal line extending in the second direction; and
in the first region, the first signal line and the second signal line intersects with each other in an insulated manner.

17. The display panel according to claim 16, wherein
at least one of the signal lines comprises a first line segment and a second line segment that are electrically connected to each other, at least part of the first line segment is located in the first region, and the second line segment is located in the second region;
the first line segment and the second line segment of the first signal line are located in different layers; and
the first line segment and the second line segment of the second signal line are located in a same layer, or the first line segment and the second line segment of the second signal line are located in different layers.

18. The display panel according to claim 1, further comprising:
a shift register unit located in a non-display region;
wherein the shift register unit comprises a first shift register unit, and the hollow portion is arranged at a side of the first shift register unit adjacent to the display region.

19. The display panel according to claim 18, wherein
first shift register units are cascaded, and
the hollow portion is arranged between two adjacent first shift register units along an arrangement direction of the first shift register units; or
wherein
the shift register unit comprises a second shift register unit located at a side of the first shift register unit away from the display region, and
the hollow portion is located between the first shift register unit and the second shift register unit.

20. A display device, comprising a display panel,
wherein the display panel comprises:
a substrate;
a driving layer; and
a light-emitting device,
wherein the driving layer and the light-emitting device are provided at a side of the substrate, the driving layer comprises inorganic layers, and at least one of the inorganic layers has a hollow portion;
wherein the display panel has a display region comprising a first region and a second region, and the first region comprises the hollow portion;
wherein the first region comprises the light-emitting device, the light-emitting device at least partially overlaps with the hollow portion along a direction perpendicular to a plane of the substrate, the second region comprises the light-emitting device and pixel circuits located in the driving layer, and the pixel circuits coupled to the light-emitting device in the first region are located in the second region; and
wherein the display region comprises signal lines located in the driving layer, the signal lines are coupled to pixel circuits, and at least one of the signal lines penetrates the first region and the second region in an extending direction thereof.
